(19) United States
(12) Patent Application Publication
(10) Pub. No.: US 2009/0033418 A1
(43) Pub. Date: Feb. 5, 2009

(54) Training sequence and digital linearization process for power amplifier

(75) Inventors: Daniel Wayne Ericson, Hollis, NH (US); Jun Ni, Burlington, MA (US)

Correspondence Address: Brian C. Oakes;Tyco Electronics Corporation, Suite 140, 4550 New Linden Hill Road, Wilmington, DE, 19808-2952, US

(73) Assignee: M/A-Com, Inc.

(21) Appl. No.: 11/888,937

(22) Filed: Aug. 3, 2007

(51) Int. Cl. H03F 1/26

(52) U.S. Cl. 330/149

(57) ABSTRACT

A training sequence and digital linearization process for a power amplifier are provided. In particular, a system for maintaining linear operation of an amplifier is includes an estimation component configured to determine compensation coefficients. The system further includes a digital pre-distorter configured to compensate for non-linear operation of the amplifier based on the compensation coefficients. The compensation coefficients are determined based on a training sequence signal having a time synchronization portion and a linearization sequence portion.

### BACKGROUND OF THE INVENTION

This invention relates generally to power amplifiers, and more particularly, to a training sequence and linearization process for power amplifiers used in radio communication.

Amplifiers operate such that the output increases linearly based on an input signal until the amplifier becomes saturated (often referred to as clipping) and thereafter operates in a non-linear manner. The result of this non-linear operation in a saturated state includes, for example, distortion.

In wireless technologies, for example, Wideband Code Division Multiple Access (WCDMA) and Worldwide Interoperability for Microwave Access (WiMax) wireless communication standards, high peak average ratio (PAR) operation occurs. In these types of systems and other amplitude modulated communication systems using, for example, high speed data radios, a power amplifier, such as a radio frequency (RF) power amplifier in a transmitter, can operate at high power that results in non-linear operation. When operating in this non-linear region, out of band interference is generated. This out of band interference affects communication quality and may also fail to meet certain communication guidelines (e.g., FCC guidelines). Accordingly, some radios may have operate at a power level much below the maximum power rating for the radio. For example, a 100 watt radio may have to operate at one watt to comply with communication guidelines or to ensure proper undistorted communications. Thus, the operating range of these radios is reduced, thereby limiting the usefulness of the radios.

Linearization techniques are known and used to correct for the non-linear operation of amplifiers. The techniques are implemented using both analog and digital methods. For example, it is known to use a common slot in Time Division Multiple Access (TDMA) systems to transmit a training sequence used for linearization. However, although these types of digital linearization methods typically provide better performance than analog linearization methods, these digital methods usually require significantly more processing power for computations or extra time to accommodate the training process. The increased need for processing power can reduce the useful battery life of radios and increase the complexity of the controls needed for the radio. The extra time needed can add delays to the overall system and affect system performance.

### BRIEF DESCRIPTION OF THE INVENTION

In accordance with an exemplary embodiment, a system for maintaining linear operation of an amplifier is provided that includes an estimation component configured to determine compensation coefficients. The system further includes a digital pre-distorter configured to compensate for non-linear operation of the amplifier based on the compensation coefficients. The compensation coefficients are determined based on a training sequence signal having a time synchronization portion and a linearization sequence portion.

In accordance with another exemplary embodiment, a training sequence signal for maintaining linear operation of an amplifier is provided. The training sequence signal includes a time synchronization portion having a first amplitude causing the amplifier to operate in a linear-region and a linearization sequence portion having a second amplitude causing the amplifier to operate in a non-linear region.

In accordance with yet another exemplary embodiment, a method for maintaining the linear operation of an amplifier is provided. The method includes transmitting a training sequence signal having a time synchronization portion and a linearization sequence portion. The method further includes performing at least one of channel access request, signal detection, time synchronization of a wireless receiver and frequency synchronization of a wireless receiver based on at least one response from the time synchronization portion. The method also includes performing linearization of the amplifier based on at least one response from the linearization sequence portion.

### BRIEF DESCRIPTION OF THE DRAWINGS

FIG. 1 is a block diagram of system constructed in accordance with various embodiments of the invention for maintaining the linear operation of an amplifier.

FIG. 2A is a block diagram illustrating linear operation of a power amplifier.

FIG. 2B is a block diagram illustrating linearization performed in accordance with various embodiments of the invention.

FIG. 3 is a graph of a training sequence generated in accordance with various embodiments of the invention.

FIG. 4 is a flowchart of a method in accordance with various embodiments of the invention that uses a training sequence to perform synchronization and linearization.

FIG. 5 is a graph of responses to a training sequence grouped in bins in accordance with various embodiments of the invention.

FIG. 6 is a graph illustrating a weighting of responses to training sequences for determining compensation coefficients in accordance with various embodiments of the invention.

### DETAILED DESCRIPTION OF THE INVENTION

The foregoing summary, as well as the following detailed description of certain embodiments of the present invention, will be better understood when read in conjunction with the appended drawings. To the extent that the figures illustrate diagrams of the functional blocks of various embodiments, the functional blocks are not necessarily indicative of the division between hardware circuitry. Thus, for example, one or more of the functional blocks (e.g., processors or memories) may be implemented in a single piece of hardware (e.g., a general purpose signal processor or a block or random access memory, hard disk, or the like). Similarly, the programs may be stand alone programs, may be incorporated as subroutines in an operating system, may be functions in an installed software package, and the like. It should be understood that the various embodiments are not limited to the arrangements and instrumentality shown in the drawings.

For simplicity and ease of explanation, the invention will be described herein in connection with various embodiments thereof. Those skilled in the art will recognize, however, that the features and advantages of the various embodiments may be implemented in a variety of configurations. It is to be understood, therefore, that the embodiments described herein are presented by way of illustration, not of limitation.

As used herein, an element or step recited in the singular and proceeded with the word “a” or “an” should be understood as not excluding plural said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property. Additionally, the arrangement and configuration of the various components described herein may be modified or change, for example, replacing certain components with other components or changing the order or relative positions of the components.

Various embodiments of the present invention provide a training sequence and digital linearization process for maintaining the linear operation of an amplifier. The various embodiments may be implemented in connection with any type of system having an amplifier (e.g., power amplifier), such as, in a transmitter in a wireless communication system (e.g., a transmitter in a high speed data radio providing land mobile radio (LMR) communications).

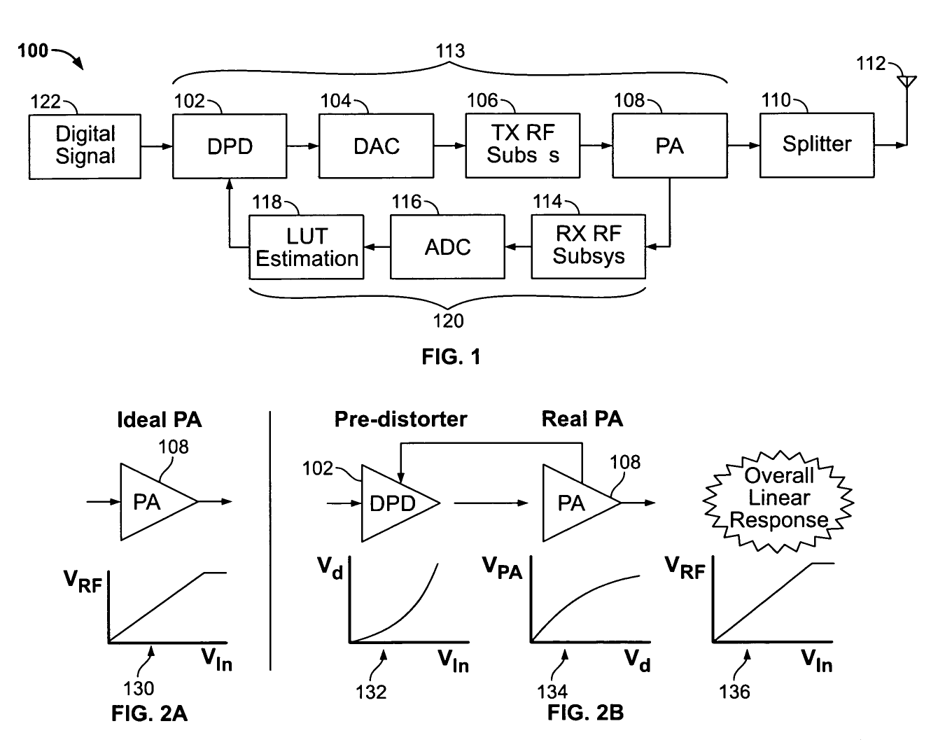

FIG. 1 illustrates a system 100 constructed in accordance with various embodiments of the invention for maintaining the linear operation of an amplifier. The system 100 may be configured, for example, as a transceiver for a wireless communication system (e.g., WCDMA or WiMax system). The system 100 includes a digital pre-distorter (DPD) 102 that includes one or more lookup tables and is connected to a digital to analog converter (DAC) 104. The DAC 104 is connected to a transmission radio frequency subsystem (TX RF Subsystem) 106. The TX RF Subsystem 106 includes, for example, up-conversion and amplification components (not shown) as can be appreciated by one skilled in the art. The TX RF Subsystem 106 is connected to a power amplifier (PA) 108. It should be appreciated that the PA 108 in the various embodiments is any type of amplifier that is, for example, the final amplification stage in the system 100. The PA 108 may be, for example, a Class B amplifier, a Class C amplifier, a Class D amplifier, among others.

The PA 108 is connected to a splitter 110. The output of the splitter 110 is split between an antenna 112 and a receiver radio frequency subsystem (RX RF Subsystem) 114 that may include, for example, a down-conversion component (not shown) as can be appreciated by one skilled in the art. It should be noted that a significantly larger amount of the output energy from the PA 108 is provided to the antenna 112 and to be received, for example, by one or more wireless receivers. The ratio of the power split may be, for example, 30 decibels (dB) to 40 dB. The RX RF Subsystem 114 is connected to an analog to digital converter (ADC) 116. The ADC 116 is connected to a lookup table estimation (LUT Estimation) component 118. The LUT estimation component estimates lookup table coefficients used by the lookup table of the DPD 102 as described in more detail herein. It should be noted that the RX RF Subsystem 114, the ADC 116 and the LUT Estimation component 118 generally define a linearization receiving chain or feedback loop 120.

In operation, on a transmitter side 113 of the system 100, namely the DPD 102, DAC 104, TX RF Subsystem 106 and PA 108, a digital signal 122, for example, a transmit signal, is received and is processed by the DPD 102. In particular, the DPD 102 adjusts the amplitude and phase to compensate for non-linear effects as described in more detail herein and to perform digital linearization. In general, the DPD 102 uses lookup table coefficients determined by the LUT Estimation component 118 to adjust the phase and amplitude of the transmit signal, which may be based on the signal frequency or amplitude. It should be noted that the lookup table coefficients are based on the results of the training sequence as described in more detail herein. After being processed by the DPD 102 (e.g., phase and amplitude adjusted), the transmit signal is then converted to an analog signal by the DAC 104 and is upconverted and amplified (e.g., pre-amplified) by the TX RF Subsystem 104. Thereafter, the transmit signal is amplified by the PA 108, the output of which is provided to the antenna 112 through the splitter 110. The transmit signal is then transmitted from the antenna 112.

Some of the energy of the output of the PA 108 is provided to the linearization receiving chain 120. The linearization receiving chain 120 down converts the signal using the RX RF Subsystem 114 and then converts the down-converted analog signal back to a digital signal using the ADC 116. The LUT Estimation component 118 then computes LUT coefficients based on the training sequence and a binning process with weighting factors as described in more detail herein.

As shown in FIG. 2A, the PA 108 should operate linearly as shown in the graph 130 with the horizontal axis representing input voltage to the PA 108 and the vertical axis representing output voltage (e.g., RF voltage) output from the PA 108. However, as the PA 108 is driven to higher power levels, the PA 108 will begin to exhibit non-linear effects. The DPD 102 compensates for non-linear effects as shown in FIG. 2B such that the system 100 functions in a linear manner (e.g., maintains linear operation of the PA 108). It should be noted that the DPD 102 uses a lookup table based in/out process where an output is generated using a lookup table based on a received input. Thus, the lookup table used by the DPD 102 (e.g., a lookup table stored in memory of the system 100 or of the DPD 102) may be defined by a graph 132 wherein the horizontal axis represents an input voltage (Vin) and the vertical axis represents a distorted output voltage (Vd). In particular, Vin is the index (e.g., address in a table or matrix) to identify the location of the distortion/compensation coefficient to use and Vd is the content at that location in the table, which in one embodiment, is a distortion/compensation coefficient.

The output of the DPD 102 generates a signal that drives the PA 108 after being converted to an analog signal by the DAC 104 and upconverted by the TX RF Subsystem 108. In particular, the voltage V_{d} is related to the voltage (V_{PA}) of the PA 108 such as the power output of the PA 108 as shown in graph 134, which results in an overall linear response as shown in the graph 136 wherein the horizontal axis represents the received input voltage (Vin) and the vertical axis represents the output voltage (V_{RF}) of the PA 108. The response of the DPD 102 as shown in graph 132 is the inverse function of the response of the PA 108 shown in graph 134. Accordingly, linearization of the PA 108 is provided to maintain linear operation.

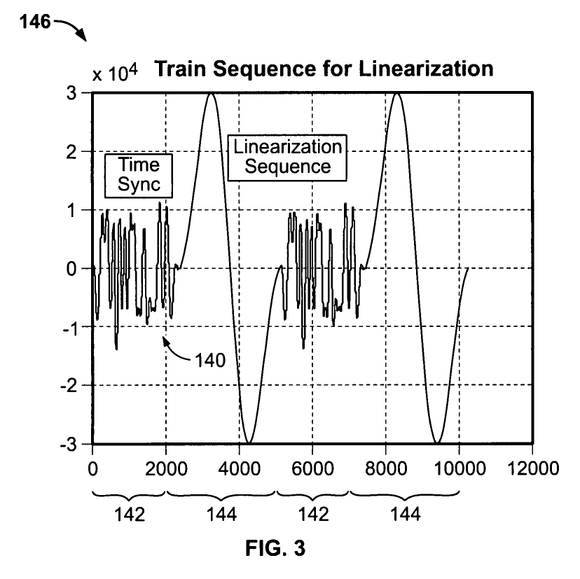

The values for the distortion/compensation coefficients that are estimated using the LUT Estimation component 118 and then stored in the lookup table of the DPD 102 are determined using a training sequence 140 (illustrated as a training sequence signal) in the graph 146 of FIG. 3. The training sequence 140 is also used for time synchronization as described herein. It should be noted that the training sequence 140 has a constant phase, for example, in one embodiment the training sequence 140 has a constant phase of 0 or is a real signal. The horizontal axis of the graph 146 represents time (e.g., time in microseconds) and the vertical axis represents amplitude (e.g., the power input to the PA 108).

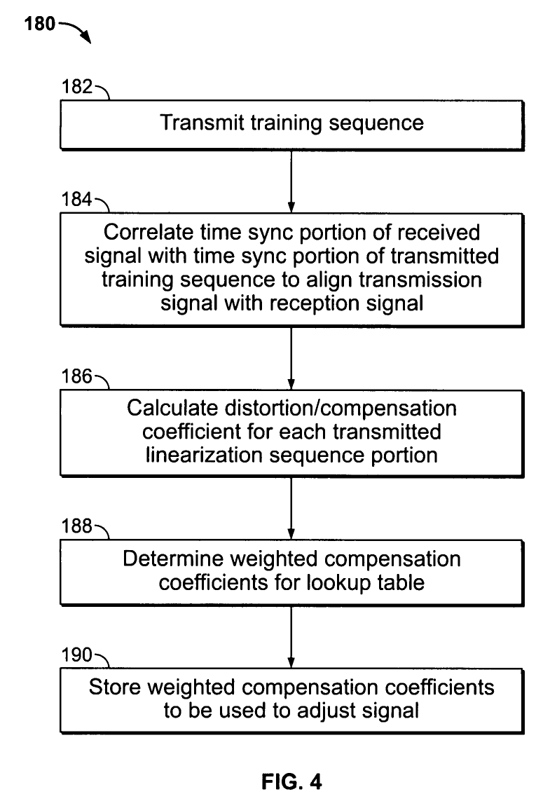

Various embodiments of the invention use the training sequence 140 to perform synchronization and linearization as illustrated by the method 180 shown in FIG. 4. Specifically, at 182, the training sequence 140 is transmitted by a transmitter, for example, the transmitter side 113 of the system 100. The training sequence 140 includes a time synchronization (time sync) portion 142 and a linearization sequence portion 144. The training sequence 140 may be generated, for example, by the DPD 102 during a training period. The time sync portion 142 is used to time synchronize the transmission chain and the reception chain of the system 100 (shown in FIG. 1), and in particular, the transmitter side 113 and the linearization receiving chain 120. Specifically, the transmission chain and the reception chain of the system 100 may include delays. The time sync portion 142 is used to align the transmission signal with the receiving signal at 184. In particular, the LUT Estimation component 118 uses a copy of the time sync portion 142 and performs correlation of the received signal with this copy of the time sync portion 142. The delay between the transmission signal and the received signal is derived from the peak position of the correlation.

Specifically, the time sync portion 142 has a small amplitude, which as used herein, means that the PA 108 is driven only within a linear region. Accordingly, the time sync portion 142 is not distorted. The time sync portion 142 is a wide bandwidth pseudo-random noise (PN) sequence such that the correlation of the sequence is symmetric. The PN sequence or pattern may be generated by any type of pseudo random sequence generator, for example, a five bit linear feedback shift register (LFSR). The time sync portion 142 in various embodiments typically occupies the full channel bandwidth (e.g., the entire bandwidth for a particular transmission channel). Because the correlation is symmetric, the correlation result can next be interpolated to increase the accuracy of the position and value of the correlation peak. Thus, the time sync portion 142 is a lower energy randomly generated sequence signal that is used for time synchronization, which may include, for example, signal detection, time synchronization and frequency synchronization.

The linearization sequence portion 144 includes a linearization sequence that has a large amplitude, which as used herein, means that the PA 108 is driven to a non-linear region of operation. The linearization sequence portion 144 also includes a narrower bandwidth to reduce the adjacent channel power (ACP) during the training period. As shown in graph 146, the linearization sequence portion 144 is a slow ramp up and ramp down signal. The bandwidth of the signal in various embodiments in less than 10% of the channel bandwidth so the ACP is minimal. The linearization sequence portion 144 may use synchronization information determined from transmission of the time sync portion 142. For example, let Tₜₛ be the time sync portion 142 and Rₚₐ be that are the samples received by the linearization receiving chain 120 based on the transmission of the training sequence 140. Tₜₛ (0,1, . . . L−1) is a real sequence with length of L. The correlation (Cor) of the time sync portion 142 and the received samples is obtained as follows:

Cor(i)=ΣRₚₐ(i+m)×Tₜₛ(m) Equation 1

where m=0˜L−1 and i=0˜P−1,

P is the length of the training sequence 140

The peak position of the correlation value (defined as max(Cor) and which is the maximum value) is used to estimate the delay between the transmitted and received samples and is used to normalize the received samples. The normalization factor (K) is defined as follows:

K=E(Tₜₛ)/max(Cor) Equation 2

The energy of the time sync portion is defined as follows:

E(Tₜₛ)=Σ|Tₜₛ(m)|², where m=0˜L−1 Equation 3

For each sequence defined by each of the linearization sequence portions 144 (shown in FIG. 3) a distortion/compensation coefficient is calculated at 186. In particular, let Tₗₙ be the linearization sequence portion 144 and Rₗₙ be the received linearization sequence portion of the received signal. The length of Tₗₙ and Rₗₙ is M. Then, in various embodiments, the estimated distortion/compensation coefficient is determined as follows: the received samples Rₗₙ are multiplied by the normalization factor K, such that RNₗₙ=Rₗₙ×K. The conjugate of that normalized received sample is then determined and the result divided by the power of the normalized received sample. The distortion/compensation coefficient is then defined by:

Cmp(i)=Tᵢₙ(i)×conj(RNₗₙ(i)/|RNₗₙ(i)|², where i=0˜M−1 Equation 4

The distortion/compensation coefficients are accordingly calculated for each of a plurality of response signals (e.g., 1000 received signal samples), which calculation is an estimation by the LUT Estimation component 118 (shown in FIG. 1). The distortion/compensation coefficients for each of the response signals are then binned as described below to calculate a weighted compensation coefficient for each bin (with each of the bins corresponding to a different amplitude level). The weighted compensation coefficients are then used to generate a lookup table for the DPD 102 (shown in FIG. 1). For example, let N be the size of the lookup table. In various embodiments, N is 512 or larger. However, N may be smaller or larger as desired or needed.

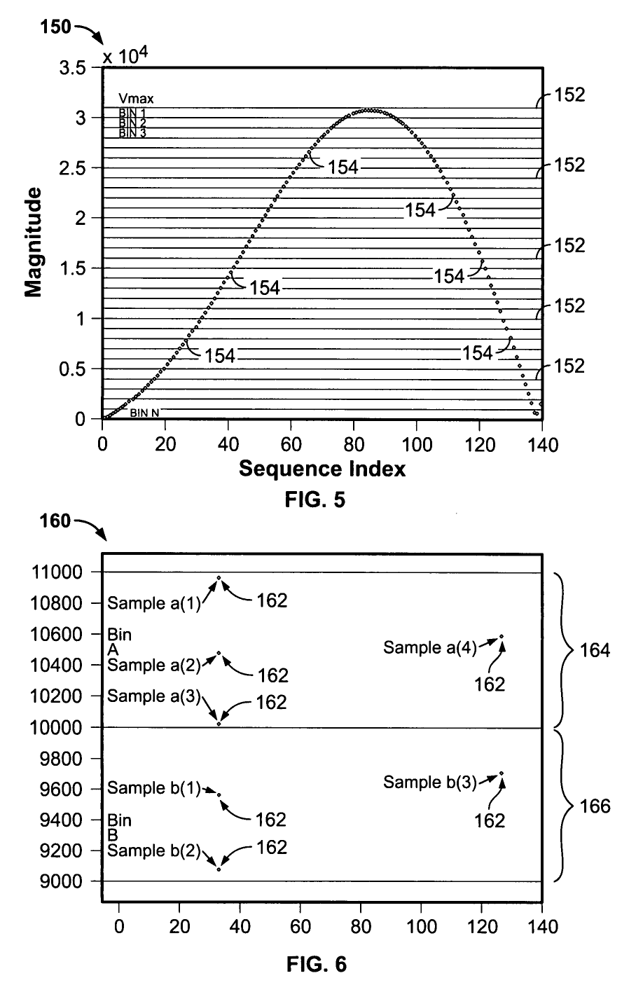

Specifically, the response signals from one or more training sequences 140 are grouped into N different bins according to the magnitude of the normalized received samples RNᵢₙ as shown in the graph 150 illustrated in FIG. 5 to determine a weighted compensation coefficient at 188, wherein Vₘₐₓ is the maximum magnitude and each bin covers a range of Vₘₐₓ/N. For example, as shown in the graph 150, the horizontal axis represents an index number for the sequence (e.g., the first training sequence 140 transmitted, the fifth training sequence 140 transmitted and up to the Mth training sequence 140 transmitted) and the vertical axis represents the magnitude corresponding to each bin. As shown, each bin (e.g., Bin 1, Bin 2, Bin 3 . . . Bin N) may be delineated by horizontal lines 152 on the graph 150. Each bin corresponds to a particular magnitude range for the received response signals. Each response signal is then indicated, for example, by a marker 154 (e.g., a point on the graph 150) in that corresponding bin. Thus, the counts for each bin are determined horizontally across the graph 150. Accordingly, the graph 150 defines a distribution curve of the response signals from the plurality of training sequences 140 transmitted.

The weighted compensation coefficient is then determined for each bin. Specifically, the weighted compensation coefficient is the summation of compensation coefficients of all the receiving samples belonging to the particular bin that have been assigned a weighting factor. For example, as shown in FIG. 6, the weighting factor for each sample is based on the distance between the center of the bin to the sample's magnitude and signal to noise ratio (SNR), which samples are then summed together to calculate the weighted compensation coefficient. The distance is the Euclidean distance. The SNR measurement is based on the implementation. For example, the SNR can be determined by measuring the noise power. This can be performed by setting the output of the digital signal 122 to zero.

For the bins illustrated by the graph 160 in FIG. 6 (Bin A 164 and Bin B 166), a plurality of samples 162 (illustrated by points in the bins and corresponding to the markers 154 in FIG. 5) are identified based on the energy level or magnitude of each sample 162. For Bin A 164, sample a(2) 162 is closest to the center of Bin A 164 and accordingly is assigned the largest weighting factor with the sample a(1) farthest from the center of Bin A 164 assigned the smallest weighting factor. For sample j, the weighting factor Wⱼ is calculated as follow: Wⱼ=SNRⱼ/(1+α×Dⱼ×SNRⱼ) where Dⱼ is the distance, SNRⱼ is the signal to noise ratio and a is a constant ranging between 0.01 to 0.1. It should be noted that performance is quite insensitive to the choice of α, the value (e.g., optimal value) of which can be determined, for example, by testing. The weighting factor Wⱼ then needs to be normalized so that the sum of the weighting factors for all the samples 162 in a single bin, for example, Bin A 164 is one. Thus, for example, in Bin 1 164, the samples 162 may be assigned the following weighting factors:

Sample a(1)=0.1

Sample a(2)=0.5

Sample a(3)=0.1

Sample a(4)=0.3

For Bin B 166, and for example, the samples 162 may be assigned the following weighting factors:

Sample b(1)=0.5

Sample b(2)=0.2

Sample b(3)=0.3

The process is repeated for each bin, for example, for each bin shown in FIG. 5. The weighted compensation coefficient for each bin is then stored in the lookup table at 190 and that is used by the DPD 102 (shown in FIG. 1). Accordingly, using the determined distortion/compensation coefficients that are stored in the lookup table (e.g., by the DPD 102), the transmission signal is adjusted. For example, the index I to the lookup table with size of N is N×Vᵢₙ/Vₘₐₓ rounded to the nearest integer toward minus infinity and Vᵢₙ is the magnitude of the transmission signal. The transmission signal is then multiplied with the Lut(I). Lut(I) is the distortion/compensation coefficient stored in the lookup table. The LUT value is retrieved based on a transmission level for the system 100.

Thus, using the training sequence 140, synchronization and linearization may be performed. In particular, using the time sync portion 142 of the training sequence 140, channel access request, signal detection, time synchronization and frequency synchronization may be performed. Moreover, a set of PN sequences can be predefined for a radio to request channel access. The linearization sequence portion 144 of the training sequence 140 can be used to for automatic gain control (AGC). For example, the linearization sequence portion 144 is a slow ramp up/down signal and a wireless receiver can use the linearization sequence portion 144 for signal energy estimation and gain control. Accordingly, no common linearization slot is needed because during the period that the wireless receiver uses the training sequence 140 for channel access request, signal detection, AGC, time and frequency synchronization, the wireless transmitter also uses the training sequence 140 for linearization. Moreover, real time compensation may be performed such that out of band transmissions are minimized or avoided completely. The training sequence 140 also may be used as a preamble to a Time Division Multiple Access (TDMA) slot.

It should be noted that the various embodiments may be implemented in software, hardware or a combination thereof. For example, the various embodiments may be implemented in an application specific integrated circuit (ASIC) or a field-programmable gate array (FPGA).

It should be noted that modifications and variations to the various embodiments are contemplated. For example, the number, relative positioning and operating parameters of the various components may be modified based on the particular application, use, etc. The modification may be based on, for example, different desired or required operating characteristics. Also, the length and timing of the sequences may be changed.

Accordingly, it is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description.

The scope of the various embodiments of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112, sixth paragraph, unless and until such claim limitations expressly use the phrase “means for” followed by a statement of function void of further structure.

What is claimed is:

1. A system for maintaining linear operation of an amplifier, the system comprising:
an estimation component configured to determine compensation coefficients; and
a digital pre-distorter configured to compensate for non-linear operation of the amplifier based on the compensation coefficients, wherein the compensation coefficients are determined based on a training sequence signal having a time synchronization portion and a linearization sequence portion.

2. A system in accordance with claim 1 wherein the linearization sequence portion is transmitted at a substantially higher amplitude than the time synchronization potion.

3. A system in accordance with claim 1 wherein the time synchronization portion is transmitted at an amplitude that causes the amplifier to operate in a linear region and the linearization sequence portion is transmitted at an amplitude that causes the amplifier to operate in a non-linear region.

4. A system in accordance with claim 1 wherein the time synchronization portion is transmitted at a substantially wider bandwidth than the linearization sequence portion.

5. A system in accordance with claim 1 wherein the training sequence signal is transmitted at a constant phase.

6. A system in accordance with claim 1 wherein the estimation component determines the compensation coefficients based on a binning of a plurality of signal responses based on a plurality of transmitted linearization sequence portions.

7. A system in accordance with claim 6 wherein the estimation component determines the compensation coefficients based on a weighting of signal responses in each of a plurality of bins resulting from the binning process.

8. A system in accordance with claim 7 wherein the estimation component determines the weighting based on a distance of each of the responses from a center of a bin and a signal to noise ratio (SNR).

9. A system in accordance with claim 1 wherein the time synchronization portion comprises a pseudo-random sequence.

10. A system in accordance with claim 1 wherein the pre-distorter is configured for real time compensation.

11. A training sequence signal for maintaining linear operation of an amplifier, the training sequence signal comprising:
a time synchronization portion having a first amplitude causing the amplifier to operate in a linear-region; and
a linearization sequence portion having a second amplitude causing the amplifier to operate in a non-linear region.

12. A training sequence signal in accordance with claim 11 wherein the time synchronization portion comprises a pseudo-random sequence.

13. A training sequence signal in accordance with claim 11 wherein the training sequence signal comprises a fixed phase signal.

14. A training sequence signal in accordance with claim 11 wherein the training sequence signal comprises a real signal.

15. A method for maintaining the linear operation of an amplifier, the method comprising:
transmitting a training sequence signal having a time synchronization portion and a linearization sequence portion;
performing at least one of channel access request, signal detection, time synchronization of a wireless receiver and frequency synchronization of a wireless receiver based on at least one response from the time synchronization portion; and
performing linearization of the amplifier based on at least one response from the linearization sequence portion.

16. A method in accordance with claim 15 further comprising driving the amplifier in a linear region during transmission of the time synchronization portion and driving the amplifier in a non-linear region during transmission of the linearization sequence portion.

17. A method in accordance with claim 15 further comprising generating a pseudo-random sequence to define the time synchronization portion.

18. A method in accordance with claim 15 further comprising determining compensation coefficients for the amplifier based on a plurality of signal responses to the linearization sequence portion.

19. A method in accordance with claim 18 further comprising binning the signal responses into a plurality of bins.

20. A method in accordance with claim 19 further comprising weighting the response signals corresponding to each of the plurality of bins.
